(19) United States
(12) Patent Application Publication
(10) Pub. No.: US 2026/0195506 A1
(43) Pub. Date: Jul. 9, 2026

(54) METHOD AND DEVICE FOR PREDICTING INLET NOx CONCENTRATION OF DENITRIFICATION SYSTEM IN THERMAL POWER PLANT

(71) Applicant: DATANG ENVIRONMENT INDUSTRY GROUP COL., LTD., Beijing (CN)

(72) Inventors: Lei MENG, Beijing (CN); Yuyong BAI, Beijing (CN); Yan YANG, Beijing (CN); Liming ZHU, Beijing (CN); Lijian LI, Beijing (CN); Shuang XIA, Beijing (CN); Mingsheng DU, Beijing (CN); Guoqing ZHAO, Beijing (CN); Xiaoman TIAN, Beijing (CN); Jialiang WANG, Beijing (CN); Siwei PENG, Beijing (CN); Wu MA, Beijing (CN); Xiaoyue MA, Beijing (CN); Fei LI, Beijing (CN); Yang GAO, Beijing (CN); Ziyi SONG, Beijing (CN)

(73) Assignee: DATANG ENVIRONMENT INDUSTRY GROUP COL., LTD., Beijing (CN)

(21) Appl. No.: 19/121,397

(22) PCT Filed: Jan. 21, 2025
(86) PCT No.: PCT/CN2025/073616

§ 371 Date: Apr. 15, 2025

(30) Foreign Application Priority Data
Jan. 6, 2025 (CN) 202510016580.1

(51) Int. Cl. G06F 30/27

(52) U.S. Cl. CPC G06F 30/27

(57) ABSTRACT

Disclosed is a method and device for predicting inlet NOx concentration of a denitrification system in a thermal power plant considering measurement delay. The method includes: determining factors influencing inlet NOx concentration of a denitrification reactor, and collecting data of inlet NOx concentration and factors influencing the inlet NOx concentration; determining measurement delay times of inlet NOx concentration, and correcting inlet NOx concentration; using the Fourier transform correlation coefficient method to calculate the correlation coefficients between inlet NOx concentration and each influencing factor, and determining output variables and input characteristic parameter variables used for prediction; according to the determined output variables and input characteristic parameter variables, using a machine-learning algorithm based on physical constraints to train and complete a prediction model; and collecting factors influencing the inlet NOx concentration at the current moment, and feeding into the prediction model to obtain inlet NOx concentration value at the current moment.

### CROSS-REFERENCE TO RELATED PATENT APPLICATIONS

This application claims a priority from the Chinese Patent Application No. 202510016580.1, filed with the Chinese Patent Office on Jan. 6, 2025, entitled “METHOD AND DEVICE FOR PREDICTING INLET NOX CONCENTRATION OF DENITRIFICATION SYSTEM IN THERMAL POWER PLANT”, content of which is incorporated herein by reference in its entirety.

### FIELD OF THE INVENTION

The disclosure relates to the technical field of flue gas denitrification in coal-fired power plants, in particular to a method and a device for predicting inlet NOx concentration of a denitrification system in a thermal power plant considering measurement delay.

### BACKGROUND OF THE INVENTION

With the promulgation of a series of national policies and regulations, the atmospheric pollutant emissions of coal-fired power plants have been incorporated into strict supervision. A large amount of atmospheric pollutants will be generated during the coal combustion process, causing serious environmental pollution problems. NOx is one of the main pollutants emitted by coal-fired power plants. Once emitted into the atmosphere, it undergoes a series of physical and chemical reactions to generate various harmful substances, causing great harm to environment and human beings. Accurately measuring the inlet NOx concentration is of great significance for controlling the NOx concentration emissions at the outlet, and the accurate prediction of the real-time value of NOx at the inlet has become the key to improve the control effect of the denitrification system.

At present, both at home and abroad, the NOx components in flue gas are mainly measured in real time through a Continuous Emission Monitoring System (CEMS). However, this measurement method has disadvantages such as long time consumption for data analysis and serious lag in the feedback of measured values, resulting in inaccurate measurement results of NOx at the inlet. For this reason, many scholars have carried out research on predicting the inlet NOx concentration of denitrification. Mechanistic models are often used, that is, physical models are constructed for calculation. Some scholars also use data-driven methods to predict the inlet NOx concentration. However, there are certain problems. For example, when using a mechanistic model, the model establishment process is relatively complex and time-consuming, and it is difficult to define the parameters. The data-driven model is a model completely constructed based on the data. The model is completely limited by the collected operation data. On the one hand, when there is noise in the data, the generalization ability of the model is poor. On the other hand, the data is based on the data measured by CEMS, and this data has a certain delay, which will lead to the mismatch of the time series of the selected variable data at the same time. Predicting the inlet NOx concentration based on the delayed data is bound to be inaccurate.

Therefore, in the process of predicting the inlet NOx concentration, it is necessary to consider both the mechanistic model and the data. At the same time, the delay in the data also needs to be removed. For this reason, comprehensively considering the above factors, carrying out the prediction of the inlet NOx concentration of denitrification is an urgent problem to be solved in the denitrification control process of thermal power plants.

### SUMMARY OF THE INVENTION

The purpose of the present disclosure is to provide a method and a device for predicting inlet NOx concentration of a denitrification system in a thermal power plant considering measurement delay, aiming to solve the above problems in the prior art.

The present disclosure provides a method for predicting inlet NOx concentration of a denitrification system in a thermal power plant considering measurement delay, including:
S101: determining factors influencing inlet NOx concentration of a denitrification reactor, and collecting data of the inlet NOx concentration and the factors influencing the inlet NOx concentration of the denitrification reactor;
S102: determining measurement delay times of the inlet NOx concentration, and correcting the inlet NOx concentration according to the measurement delay times to obtain the inlet NOx concentration without delay;
S103: using a Fourier transform correlation coefficient method to calculate correlation coefficients between the inlet NOx concentration and each influencing factor, obtaining a delay time between each influencing factor and the inlet NOx concentration according to the correlation coefficients, correcting each influencing factor according to the delay time to obtain the data of the factors influencing the inlet NOx concentration without delay, and determining output variables and input characteristic parameter variables used for prediction;
S104: based on the inlet NOx concentration without delay and the data of the factors influencing the inlet NOx concentration without delay, and according to the determined output variables and input characteristic parameter variables, using a machine learning algorithm based on physical constraints to train and complete a prediction model; and
S105: collecting the data of the factors influencing the inlet NOx concentration at the current moment, making a correction according to the calculated delay time, feeding into the prediction model, and obtaining the inlet NOx concentration value at the current moment.

The present disclosure provides a device for predicting inlet NOx concentration of a denitrification system in a thermal power plant considering measurement delay, including:
a collection module for determining factors influencing inlet NOx concentration of a denitrification reactor, and collecting data of the inlet NOx concentration and the factors influencing the inlet NOx concentration of the denitrification reactor;
a correction module for determining measurement delay times of the inlet NOx concentration, and correcting the inlet NOx concentration according to the measurement delay times to obtain the inlet NOx concentration without delay;
a calculation module for using a Fourier transform correlation coefficient method to calculate correlation coefficients between the inlet NOx concentration and each influencing factor, obtaining a delay time between each influencing factor and the inlet NOx concentration according to the correlation coefficients, correcting each influencing factor according to the delay time to obtain the data of the factors influencing the inlet NOx concentration without delay, and determining output variables and input characteristic parameter variables used for prediction; and
a prediction model module for, based on the inlet NOx concentration without delay and the data of the factors influencing the inlet NOx concentration without delay, and according to the determined output variables and input characteristic parameter variables, using a machine learning algorithm based on physical constraints to train and complete a prediction model; and collecting the data of the factors influencing the inlet NOx concentration at the current moment, making a correction according to the calculated delay time, feeding into the prediction model, and obtaining the inlet NOx concentration value at the current moment.

An embodiment of the present disclosure provides an electronic device including a memory, a processor, and a computer program stored on the memory and executable on the processor, in which, when the computer program is executed by the processor, the steps of the above-mentioned method for predicting inlet NOx concentration of a denitrification system in a thermal power plant considering measurement delay are implemented.

An embodiment of the present disclosure provides a computer readable storage medium on which an implementation program for information transmission is stored, in which, when the program is executed by a processor, the steps of the above-mentioned method for predicting inlet NOx concentration of a denitrification system in a thermal power plant considering measurement delay are implemented.

By adopting the embodiments of the present disclosure, both the mechanistic model and the operation data of the factors influencing the inlet NOx concentration are considered during the prediction process. At the same time, the measurement delay times of the inlet NOx concentration itself and the delay time between the inlet NOx concentration and the influencing factors are also analyzed. The established model improves the accuracy of the inlet NOx modeling, which has guiding significance for reducing the emission of pollutants and costs in coal-fired units.

### BRIEF DESCRIPTION OF THE DRAWINGS

In order to more clearly illustrate the technical solutions in one or more embodiments of this specification or in the prior art, the following will briefly introduce the accompanying drawings that need to be used in the description of the embodiments or the prior art. Obviously, the accompanying drawings described below are only some of the embodiments recorded in this specification. For those of ordinary skill in the art, other accompanying drawings can also be obtained based on these drawings without creative efforts.

FIG. 1 is a flowchart of a method for predicting inlet NOx concentration of a denitrification system in a thermal power plant considering measurement delay according to an embodiment of the present disclosure;

FIG. 2 is a schematic flowchart of a construction process of machine learning algorithm based on physical constraints according to an embodiment of the present disclosure;

FIG. 3 is a schematic flowchart of a prediction process of the inlet NOx concentration under full operating conditions according to an embodiment of the present disclosure;

FIG. 4 is a schematic diagram of a device for predicting inlet NOx concentration of a denitrification system in a thermal power plant considering measurement delay according to an embodiment of the present disclosure; and

FIG. 5 is a schematic diagram of an electronic device according to an embodiment of the present disclosure.

### DETAILED DESCRIPTION OF THE INVENTION

In order to enable the personnel in this technical field to better understand the technical solutions in one or more embodiments of this specification, the technical solutions in one or more embodiments of this specification will be clearly and completely described below in conjunction with the accompanying drawings in one or more embodiments of this specification. Obviously, the described embodiments are only a part of the embodiments of this specification, rather than all of them. Based on one or more embodiments of this specification, all other embodiments obtained by those of ordinary skill in the art without creative efforts shall fall within the protection scope of this document.

### Method Embodiment

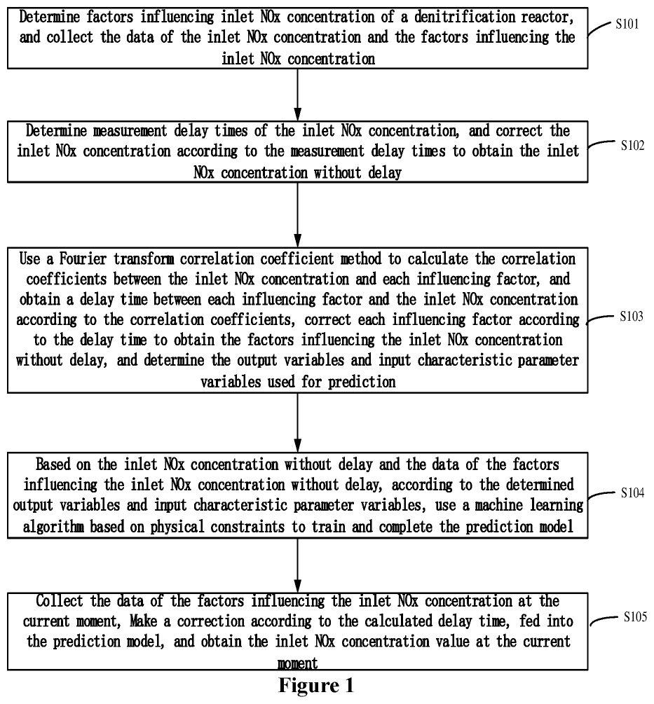

According to the embodiment of the present disclosure, there is provided a method for predicting inlet NOx concentration of a denitrification system in a thermal power plant considering measurement delay. FIG. 1 is a flowchart of the method for predicting inlet NOx concentration of a denitrification system in a thermal power plant considering measurement delay according to the embodiment of the present disclosure. As shown in FIG. 1, the method for predicting inlet NOx concentration of a denitrification system in a thermal power plant considering measurement delay according to the embodiment of the present disclosure specifically includes the following steps.

S101: Determine factors influencing the inlet NOx concentration of a denitrification reactor, and collect data of the inlet NOx concentration and the factors influencing the inlet NOx concentration of the denitrification reactor.

Specifically, according to the generation mechanism of NOx in the flue gas of the thermal power plant, the factors influencing the inlet NOx concentration are determined, including unit load, total air volume, total coal quantity, total primary air volume, total secondary air volume, and coal grinding quantity.

Further, with a predetermined sampling interval, the data of the inlet NOx concentration and the factors influencing the inlet NOx concentration of the denitrification reactor within a predetermined past time is collected from DCS system or SIS system of the thermal power plant.

S102: Determine measurement delay times of the inlet NOx concentration, and correct the inlet NOx concentration according to the measurement delay times to obtain the inlet NOx concentration without delay.

Specifically, according to the inlet NOx concentration measured by CEMS, the measurement delay time t1 including a delay time of a gas sampling system t_sampling, a delay time of a transmission pipeline t_transmission, and a response time of an analyzer t_response is determined. Herein, the delay time of a gas sampling system t_sampling is the delay caused by a sampling pipeline, a sampling pump and a filter, etc., and is determined by the ratio of the length of the sampling pipeline L1 to the flow rate of the sampling pump V1, that is, t_sampling=L1/V1. The delay time of a transmission pipeline t_transmission is the delay of the measurement signal transmitted from the sampling point to the instrument CEMS, and is determined by the transmission distance of the signal L2 and the transmission rate V2, that is, t_transmission=L2/V2. The response time of an analyzer t_response is the time required for the CEMS analyzer instrument when the input signal changes.

Further, the measurement delay time t1 is calculated according to formula 1, and the data of the inlet NOx concentration at the current time t2 is corrected, that is, the inlet NOx concentration value at time t2 is corrected to be the inlet NOx concentration value at time (t2−t1):

$$t 1 = t\_sampling + t\_transmission + t\_response . \qquad Formula 1$$

S103: Use a Fourier transform correlation coefficient method to calculate correlation coefficients between the inlet NOx concentration and each influencing factor, and obtain a delay time between each influencing factor and the inlet NOx concentration according to the correlation coefficients, correct each influencing factor according to the delay time to obtain the factors influencing the inlet NOx concentration without delay, and determine output variables and input characteristic parameter variables used for prediction.

Specifically, let the inlet NOx concentration factors be X(t), and factors influencing the inlet NOx concentration be Y(t)={y1(t), y2(t), y3(t), y4(t), y5(t), y6(t)}, where y1, y2, y3, y4, y5, y6 are the unit load, total air volume, total coal quantity, total primary air volume, total secondary air volume, and coal grinding quantity respectively, t is the index number, t=1, 2, . . . , N, and N is the number of collected inlet NOx concentration samples. Then, the Fourier cross-correlation coefficient is determined according to formula 2:

$${C}_{X Y} ( t ) = {F}^{⋀} \{ - 1 \} \{ X ( f ) * ( Y * ( f ) ) \} , \qquad Formula 2$$

where C_{XY}(t) is the Fourier cross-correlation coefficient of X(t) and Y(t); F\hat{ }{−I} is the inverse Fourier transform; X(f), Y(f) are the Fourier transforms of X(t) and Y(t); Y*(f) is the complex conjugate of Y(t); and * is the conjugate of a complex number.

Further, the Fourier correlation coefficients of X(t) and Y(t) within the time from 0 to t3 are calculated, respectively, and the moments t4, t5, t6, t7, t8, t9 corresponding to the maximum values of the Fourier correlation coefficients of y1, y2, y3, y4, y5, y6 are calculated, which are the delay times between the inlet NOx concentration and its influencing factors.

Further, according to the calculated delay times t4, t5, t6, t7, t8, t9, the collected data of the factors influencing the inlet NOx concentration at the current time T is corrected, that is, the unit load, total air volume, total coal quantity, total primary air volume, total secondary air volume, and coal grinding quantity at time T are corrected to the unit load, total air volume, total coal quantity, total primary air volume, total secondary air volume, and coal grinding quantity at times (T−t4), (T−t5), (T−t6), (T−t7), (T−t8), (T−t9), respectively.

Furthermore, it is determined that the output variable used for prediction is the corrected inlet NOx concentration value, and the input variables are the corrected unit load, total air volume, total coal quantity, total primary air volume, total secondary air volume, and coal grinding quantity.

Step S104: Based on the inlet NOx concentration without delay and the data of the factors influencing the inlet NOx concentration without delay, and according to the determined output variables and input characteristic parameter variables, use a machine learning algorithm based on physical constraints to train and complete a prediction model.

Specifically, the Zeldovich mechanism model is used to construct the prediction model according to factors such as temperature, oxygen concentration, nitrogen concentration, pressure, reaction time, and activation energy.

Further, the BP neural network model is used as the machine learning algorithm. Herein, the BP neural network model is a three-layer model including an input layer, a hidden layer, and an output layer. The input layer consists of six input variables of the corrected unit load, total air volume, total coal quantity, total primary air volume, total secondary air volume, and coal grinding quantity. The output layer is the corrected inlet NOx concentration value. The parameters of the BP neural network model are the weights and thresholds between the input layer and the hidden layer, and the weights and thresholds between the hidden layer and the output layer. The above weights and thresholds are corrected through a global error function, which is defined as formulas 3-5:

$$E ( θ ) = Data ( θ ) + λ Physic s ( θ ) ; \qquad Formula 3$$

$$Data ( θ ) = \frac{1}{2 N} {\sum }_{i = 1}^{N} {( {y}_{i} - {\hat{y}}_{Data \_ i} )}^{2} ; \qquad Formula 4$$

$$Physic ( θ ) = \frac{1}{2 N} {\sum }_{i = 1}^{N} {( {y}_{Physics \_ i} - {\hat{y}}_{Physics \_ i} )}^{2} ; \qquad Formula 5$$

where E(θ) is the global error function, and Data(θ) is the error function of the BP neural network model; Physics(θ) is the error function of the physical model; λ is the weight coefficient of the physical constraint term, which is obtained by the empirical method or through the genetic optimization algorithm; yᵢ is the actual inlet NOx concentration value; ŷ_{Data_i} is the predicted inlet NOx concentration value by the BP neural network model; and ŷ_{physics_i} is the predicted inlet NOx concentration value by the physical model.

Furthermore, by minimizing E(θ), the optimal weights and thresholds between the input layer and the hidden layer, and the weights and thresholds between the hidden layer and the output layer are obtained, and then the prediction model with the optimal physical constraints is determined.

Step S105: Collect the data of the factors influencing the inlet NOx concentration at the current moment, make a correction according to the calculated delay times, feed into the prediction model, and obtain the inlet NOx concentration value at the current moment. Specifically, the data of the factors influencing the inlet NOx concentration at the current moment is collected, and a correction is made according to the calculated delay times t4, t5, t6, t7, t8, t9, then it is fed into the prediction model with the optimal physical constraints, and the inlet NOx concentration value at the current moment is obtained.

According to the specific embodiments provided by the present disclosure, the technical effects of the embodiments of the present disclosure are as follows.

(1) The present disclosure provides a calculation method for the measurement delay of the inlet NOx concentration, provides a method for eliminating the measurement delay of the NOx concentration from the perspective of the measurement principle, and provides a more accurate real-time inlet NOx concentration measurement value, which can better match the current situation of the real-time inlet NOx concentration.

(2) The present disclosure further provides a calculation method for the delay between the factors influencing the inlet NOx concentration and the inlet NOx concentration based on the Fourier correlation coefficient method. By transforming the time-domain data into frequency-domain data, the data features at different frequencies are obtained, and the features of the data are more prominent. This technology eliminates the delay between the inlet NOx concentration and its influencing factors, making the established model more matched and more accurate.

(3) The present disclosure provides a machine learning algorithm based on physical constraints, which comprehensively considers the physical model and the machine learning algorithm model, takes into account both the operation data and the generation mechanism, and avoids the machine learning model from ignoring the physical laws due to overfitting the training data, thereby improving the generalization ability and accuracy of the model, especially in the case of insufficient data or large noise. The established model has higher accuracy and the prediction results are more in line with the actual situation.

The technical solutions of the embodiments of the present disclosure will be described in detail below in conjunction with the accompanying drawings.

As shown in FIG. 1, it specifically includes the following processes.

S101: According to the generation mechanism of NOx in the flue gas of thermal power plants, determine the factors influencing the inlet NOx concentration of the denitrification reactor, and collect the data of the inlet NOx concentration and the factors influencing the inlet NOx concentration of the denitrification reactor.

S201: According to the measurement principle of the inlet NOx concentration of the denitrification reactor, determine the measurement delay times of the inlet NOx concentration, and correct the inlet NOx concentration according to the measurement delay times to obtain the inlet NOx concentration without delay.

S301: Use the Fourier transform correlation coefficient method to analyze the correlation coefficients between the inlet NOx concentration and each influencing factor. According to the calculated correlation coefficients, obtain the delay time between each influencing factor and the inlet NOx concentration, and correct each influencing factor to obtain the factors influencing the inlet NOx concentration without delay, and then determine the output variables and input characteristic parameter variables used for prediction.

S401: The prediction model adopts a machine learning algorithm based on physical constraints.

S501: Collect the factors influencing the inlet NOx concentration at the current moment, and correct them according to the calculated delay time, then feed into the machine learning algorithm model based on physical constraints, and obtain the inlet NOx concentration value at the current moment.

Specifically, taking a 600 MW subcritical pressure boiler unit in China as an example, according to the analysis of the generation mechanism of NOx in the flue gas of thermal power plants, the main factors influencing NOx include unit load, total air volume, total coal quantity, total primary air volume, total secondary air volume, and coal grinding quantity.

Specifically, the data of the inlet NOx concentration and its influencing factors are mainly collected from the operation data of the DCS system or SIS system of the thermal power plants in the past year, with a sampling interval of 1 minute, about 525,600 pieces of sample data.

Specifically, according to the CEMS measurement equipment used in this 600 MW unit, its measurement delay times t1 is approximately 62.3 s, and the inlet NOx concentration is corrected according to the value of t1.

Specifically, the correlation coefficient method based on Fourier transform is used to calculate the delay time of the factors influencing the inlet NOx concentration. The correlation coefficients between the inlet NOx concentration and the unit load, total air volume, total coal quantity, total primary air volume, total secondary air volume, and coal grinding quantity within 0-20 s (t3 is taken as 20 s) are respectively calculated. Through calculation, the moments corresponding to the maximum correlation coefficients of the unit load, total air volume, total coal quantity, total primary air volume, total secondary air volume, and coal grinding quantity within 0-20 s are 15 s, 8 s, 12 s, 5 s, 9 s, and 18 s respectively. And the unit load, total air volume, total coal quantity, total primary air volume, total secondary air volume, and coal grinding quantity are corrected according to these moments.

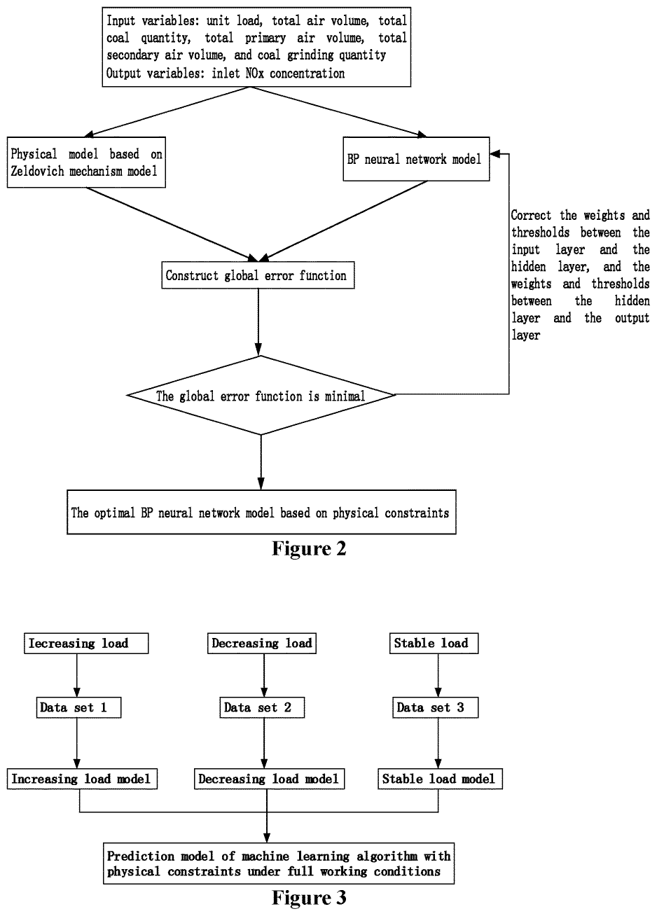

Combined with FIG. 2, specifically, the machine learning algorithm based on physical constraints mainly adds physical model constraints to the loss function of the machine learning algorithm.

The physical model constraints are mainly constructed by using the Zeldovich mechanism model. The Zeldovich mechanism model is mainly constructed according to factors such as temperature, oxygen concentration, nitrogen concentration, pressure, reaction time, and activation energy.

The machine learning algorithm mainly adopts the BP neural network algorithm. The BP neural network model is a three-layer model including an input layer, a hidden layer, and an output layer. The input layer consists of six input variables of the corrected unit load, total air volume, total coal quantity, total primary air volume, total secondary air volume, and coal grinding quantity. The output layer is the corrected inlet NOx concentration value. The parameters of the BP neural network are the weights and thresholds between the input layer and the hidden layer, and the weights and thresholds between the hidden layer and the output layer. The above weights and thresholds are mainly corrected through the global error function, which is defined as:

$$E ( θ ) = Data ( θ ) + λ Physic s ( θ ) , \qquad ( Formula 3 )$$

where E(θ) is the global error function, Data(θ) is the error function of the BP neural network model; Physics(θ) is the error function of the physical model; λ is the weight coefficient of the physical constraint term, and can be obtained by the empirical method or through the genetic optimization algorithm.

$$Data ( θ ) = \frac{1}{2 N} {\sum }_{i = 1}^{N} {( {y}_{i} - {\hat{y}}_{Data \_ i} )}^{2} ,$$

where yᵢ is the actual value of inlet NOx concentration; ŷ_{Data_i} is the predicted inlet NOx concentration value by the BP neural network model.

$$Physic ( θ ) = \frac{1}{2 N} {\sum }_{i = 1}^{N} {( {y}_{Physics \_ i} - {\hat{y}}_{Physics \_ i} )}^{2} ,$$

where yᵢ is the actual value of inlet NOx concentration; ŷ_{Physics_i} is the predicted inlet NOx concentration value by the physical model.

By minimizing E(θ), the optimal weights and thresholds between the input layer and the hidden layer, and the optimal weights and thresholds between the hidden layer and the output layer are obtained, and then the BP neural network model with the optimal physical constraints is determined.

Specifically, the factors influencing the inlet NOx concentration at the current moment are collected, and a correction is made according to the calculated delay times t4, t5, t6, t7, t8, t9, then it is fed into the BP neural network model with the optimal physical constraints, and the inlet NOx concentration value at the current moment is obtained.

Referring to FIG. 3, the present disclosure can also construct a prediction model for the inlet NOx concentration of denitrification under full operating conditions. Considering that there are conditions of increasing load, decreasing load, and stable load during the actual operation of the unit. In order to construct a prediction model under full operating conditions, the three conditions need to be comprehensively considered. Specifically, in the data collection, the data under the three conditions of increasing load, decreasing load, and stable load are collected respectively, and then the BP neural network models under physical constraints for the three conditions are established respectively. The establishment process is the same as that in method embodiment, and the embodiment provides models for multiple operating conditions.

When predicting the inlet NOx concentration at the current moment, it is necessary to collect the unit load data around 5 minutes of this time period. Based on this data, it is determined whether the unit is in the condition of increasing load, decreasing load, or stable load, and the data is input into the corresponding model respectively to obtain the predicted value of inlet NOx concentration at the current moment.

The embodiment of the present disclosure provides a method for predicting the inlet NOx concentration of the denitrification system in thermal power plants considering measurement delay. Through the method of the present disclosure, the delay time of the auxiliary variables for inlet NOx modeling relative to the inlet NOx is accurately calculated. The problem of the mismatch of the time series of the selected variable data between the inlet NOx and its influencing factors at the same time is solved, the influence of pure delay is eliminated, and the accuracy of inlet NOx modeling is improved, which has guiding significance for reducing the emission of pollutants and costs in coal-fired units.

### Device Embodiment 1

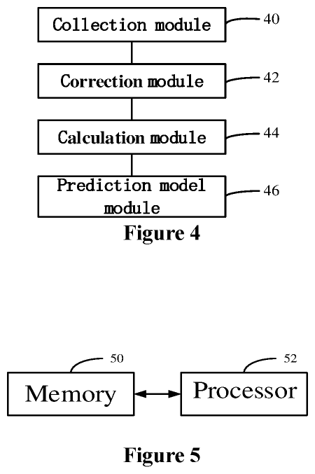

According to the embodiment of the present disclosure, a device for predicting inlet NOx concentration of a denitrification system in a thermal power plant considering measurement delay is provided. FIG. 4 is a schematic diagram of the device for predicting inlet NOx concentration of a denitrification system in a thermal power plant considering measurement delay according to the embodiment of the present disclosure. As shown in FIG. 4, the device for predicting inlet NOx concentration of a denitrification system in a thermal power plant considering measurement delay according to the embodiment of the present invention specifically includes the following modules.

A collection module 40 is used to determine the factors influencing the inlet NOx concentration of the denitrification reactor, and collect the data of the inlet NOx concentration and the factors influencing the inlet NOx concentration.

Specifically, according to the generation mechanism of NOx in the flue gas of thermal power plants, the factors influencing the inlet NOx concentration are determined, including unit load, total air volume, total coal quantity, total primary air volume, total secondary air volume, and coal grinding quantity.

Further, with a predetermined sampling interval, the data of the inlet NOx concentration and the factors influencing the inlet NOx concentration within a predetermined past time is collected from the DCS system or SIS system of the thermal power plant.

A correction module 42 is used to determine the measurement delay times of the inlet NOx concentration, and correct the inlet NOx concentration according to the measurement delay times to obtain the inlet NOx concentration without delay.

Specifically, according to the inlet NOx concentration measured by CEMS, the measurement delay time t1 including the delay time of a gas sampling system t_sampling, the delay time of a transmission pipeline t_transmission, and the response time of an analyzer t_response is determined. Herein, the delay time of a gas sampling system t_sampling is the delay caused by a sampling pipeline, a sampling pump, a filter, etc., and is determined by the ratio of the length of the sampling pipeline L1 to the flow rate of the sampling pump V1, that is, t_sampling=L1/V1. The delay time of a transmission pipeline t_transmission is the delay of the measurement signal transmitted from the sampling point to the instrument CEMS, and is determined by the transmission distance of the signal L2 and the transmission rate V2, that is, t_transmission=L2/V2. The response time of an analyzer t_response is the time required for the CEMS analyzer instrument when the input signal changes.

Further, the measurement delay time t1 is calculated according to formula 1, and the collected data of the inlet NOx concentration at the current time t2 is corrected, that is, the inlet NOx concentration value at time t2 is corrected to the inlet NOx concentration value at time (t2−t1):

$$t 1 = t\_sampling + t\_transmission + t\_response . \qquad Formula 1$$

A calculation module 44 is used to use the Fourier transform correlation coefficient method to calculate the correlation coefficients between the inlet NOx concentration and each influencing factor, and obtain the delay time between each influencing factor and the inlet NOx concentration according to the correlation coefficients, then correct each influencing factor according to the delay time to obtain the factors influencing the inlet NOx concentration without delay, and determine the output variables and input characteristic parameter variables used for prediction.

Specifically, let the inlet NOx concentration factor be X(t), and the factors influencing the inlet NOx concentration be Y(t)={y1(t), y2(t), y3(t), y4(t), y5(t), y6(t)}, where y1, y2, y3, y4, y5, y6 are the unit load, total air volume, total coal quantity, total primary air volume, total secondary air volume, and coal grinding quantity respectively, t is the index number, t=1, 2, . . . , N, and N is the number of collected inlet NOx concentration samples. Then, the Fourier cross-correlation coefficient is determined according to formula 2:

$${C}_{X Y} ( t ) = {F}^{⋀} \{ - 1 \} \{ X ( f ) * ( Y * ( f ) ) \} ; \qquad Formula 2$$

where C_{XY}(t) is the Fourier cross-correlation coefficient of X(t) and Y(t); F\hat{ }{−I} is the inverse Fourier transform; X(f), Y(f) are the Fourier transforms of X(t) and Y(t); Y*(f) is the complex conjugate of Y(t); * is the conjugate of a complex number.

Further, the Fourier correlation coefficients of X(t) and Y(t) within the time from 0 to t3 are calculated, respectively, and the moments t4, t5, t6, t7, t8, t9 corresponding to the maximum values of the Fourier correlation coefficients of y1, y2, y3, y4, y5, y6 are calculated, which are the delay times between the inlet NOx concentration and its influencing factors.

Further, according to the calculated delay times t4, t5, t6, t7, t8, t9, the collected data of the factors influencing the inlet NOx concentration at the current time T is corrected, that is, the unit load, total air volume, total coal quantity, total primary air volume, total secondary air volume, and coal grinding quantity at time T are corrected to the unit load, total air volume, total coal quantity, total primary air volume, total secondary air volume, and coal grinding quantity at times (T−t4), (T−t5), (T−t6), (T−t7), (T−t8), (T−t9) respectively.

Furthermore, it is determined that the output variable used for prediction is the corrected inlet NOx concentration value, and the input variables are the corrected unit load, total air volume, total coal quantity, total primary air volume, total secondary air volume, and coal grinding quantity.

A prediction model module 46 is used to, based on the inlet NOx concentration without delay and the factors influencing the inlet NOx concentration without delay, according to the determined output variables and input characteristic parameter variables, use a machine learning algorithm based on physical constraints to train and complete the prediction model, and collect the factors influencing the inlet NOx concentration at the current moment, then correct them according to the calculated delay time, feed into the prediction model, and obtain the inlet NOx concentration value at the current moment.

Specifically, the Zeldovich mechanism model is used to construct the prediction model according to factors such as temperature, oxygen concentration, nitrogen concentration, pressure, reaction time, and activation energy.

Further, the BP neural network model is used as the machine learning algorithm. Herein, the BP neural network model is a three-layer model including an input layer, a hidden layer, and an output layer. The input layer consists of six input variables of the corrected unit load, total air volume, total coal quantity, total primary air volume, total secondary air volume, and coal grinding quantity. The output layer is the corrected inlet NOx concentration value. The parameters of the BP neural network model are the weights and thresholds between the input layer and the hidden layer, and the weights and thresholds between the hidden layer and the output layer. The above weights and thresholds are corrected through the global error function, which is defined as formulas 3-5:

$$E ( θ ) = Data ( θ ) + λ Physic s ( θ ) \qquad Formula 3$$

$$Data ( θ ) = \frac{1}{2 N} {\sum }_{i = 1}^{N} {( {y}_{i} - {\hat{y}}_{Data \_ i} )}^{2} \qquad Formula 4$$

$$Physic ( θ ) = \frac{1}{2 N} {\sum }_{i = 1}^{N} {( {y}_{Physics \_ i} - {\hat{y}}_{Physics \_ i} )}^{2} \qquad Formula 5$$

where E(θ) is the global error function, Data(θ) is the error function of the BP neural network model; Physics(θ) is the error function of the physical model; λ is the weight coefficient of the physical constraint term, which is obtained by the empirical method or through the genetic optimization algorithm; yᵢ is the actual inlet NOx concentration value; ŷ_{Data_i} is the predicted inlet NOx concentration value by the BP neural network model; ŷ_{Physics_i} is the predicted inlet NOx concentration value by the physical model.

Further, by minimizing E(θ), the optimal weights and thresholds between the input layer and the hidden layer, and the optimal weights and thresholds between the hidden layer and the output layer are obtained, and then the prediction model with the optimal physical constraints is determined.

Furthermore, the factors influencing the inlet NOx concentration at the current moment are collected, and a correction is made according to the calculated delay times t4, t5, t6, t7, t8, t9, and it is fed into the prediction model with the optimal physical constraints to obtain the inlet NOx concentration value at the current moment.

The embodiment of the present disclosure is a device embodiment corresponding to the above mentioned method embodiment. The specific operations of each module can be understood by referring to the description of the method embodiment, and will not be repeated here.

### Device Embodiment 2

An embodiment of the present disclosure provides an electronic device. As shown in FIG. 5, it includes a memory 50, a processor 52, and a computer program stored on the memory 50 and executable on the processor 52. When the computer program is executed by the processor 52, the steps described in the method embodiment are implemented.

### Device Embodiment 3

An embodiment of the present disclosure provides a computer readable storage medium. An implementation program for information transmission is stored on the computer readable storage medium. When the program is executed by the processor 52, the steps described in the method embodiment are implemented.

The computer readable storage medium described in this embodiment includes, but is not limited to, ROM, RAM, magnetic disks, or optical disks.

Finally, it should be noted that the above embodiments are only used to illustrate the technical solutions of the present invention, rather than to limit them. Although the present invention has been described in detail with reference to the foregoing embodiments, those of ordinary skill in the art should understand that they can still modify the technical solutions described in the foregoing embodiments, or make equivalent substitutions for some or all of the technical features. However, these modifications or substitutions do not make the essence of the corresponding technical solutions deviate from the scope of the technical solutions of the embodiments of the present invention.

1. A method for predicting inlet NOx concentration of a denitrification system in a thermal power plant considering measurement delay, comprising steps of:
S101: determining factors influencing inlet NOx concentration of a denitrification reactor, and collecting data of the inlet NOx concentration and the factors influencing the inlet NOx concentration of the denitrification reactor;
S102: determining measurement delay times of the inlet NOx concentration, and correcting the inlet NOx concentration according to the measurement delay times to obtain the inlet NOx concentration without delay;
S103: using a Fourier transform correlation coefficient method to calculate correlation coefficients between the inlet NOx concentration and each influencing factor, obtaining a delay time between each influencing factor and the inlet NOx concentration according to the correlation coefficients, correcting each influencing factor according to the delay time to obtain the data of the factors influencing the inlet NOx concentration without delay, and determining output variables and input characteristic parameter variables used for prediction;
S104: based on the inlet NOx concentration without delay and the data of the factors influencing the inlet NOx concentration without delay, and according to the determined output variables and input characteristic parameter variables, using a machine learning algorithm based on physical constraints to train and complete a prediction model; and
S105: collecting the data of the factors influencing the inlet NOx concentration at the current moment, making a correction according to the calculated delay time, feeding into the prediction model, and obtaining the inlet NOx concentration value at the current moment.

2. The method according to claim 1, wherein the determining of factors influencing inlet NOx concentration of a denitrification reactor and the collecting of data of the inlet NOx concentration and the factors influencing the inlet NOx concentration comprises:
according to the generation mechanism of NOx in the flue gas of the thermal power plant, determining that the factors influencing the inlet NOx concentration include unit load, total air volume, total coal quantity, total primary air volume, total secondary air volume, and coal grinding quantity; and
with a predetermined sampling interval, collecting the data of the inlet NOx concentration and the factors influencing the inlet NOx concentration within a predetermined past time from DCS system or SIS system of the thermal power plant.

3. The method according to claim 1, wherein the determining of measurement delay times of the inlet NOx concentration and the correcting of the inlet NOx concentration according to the measurement delay times to obtain the inlet NOx concentration without delay comprises:
according to the inlet NOx concentration measured by CEMS, determining that a measurement delay time t1 includes a delay time of a gas sampling system t_sampling, a delay time of a transmission pipeline t_transmission, and a response time of an analyzer t_response, wherein the delay time of a gas sampling system t_sampling is the delay caused by the sampling pipeline, sampling pump, filter, etc., and is determined by the ratio of the length L1 of the sampling pipeline to the flow rate V1 of the sampling pump, that is, t_sampling=L1/V1, and the delay time of a transmission pipeline t_transmission is the delay of the measurement signal transmitted from the sampling point to the instrument CEMS, and is determined by the transmission distance of the signal L2 and the transmission rate V2, i.e., t_transmission=L2/V2, and the response time of an analyzer t_response is the time required for the CEMS analyzer instrument when the input signal changes; and
calculating the measurement delay time t1 according to formula 1, and correcting the collected data of the inlet NOx concentration at the current time t2, that is, correcting the inlet NOx concentration value at time t2 to the inlet NOx concentration value at time (t2−t1):
$$t 1 = t\_sampling + t\_transmission + t\_response . \qquad Formula 1$$

4. The method according to claim 1, wherein the step of S103 comprises:
letting the inlet NOx concentration factors be X(t), and the factors influencing the inlet NOx concentration be Y(t)={y1(t), y2(t), y3(t), y4(t), y5(t), y6(t)}, where y1, y2, y3, y4, y5, y6 are the unit load, total air volume, total coal quantity, total primary air volume, total secondary air volume, and coal grinding quantity respectively, t is the index number, t=1, 2, . . . , N, and N is the number of collected inlet NOx concentration samples, then, determining the Fourier cross correlation coefficient according to formula 2:
$${C}_{X Y} ( t ) = {F}^{∧} \{ - 1 \} \{ X ( f ) * ( y * ( f ) ) \} ; \qquad Formula 2$$
wherein, C_{XY}(t) is the Fourier cross correlation coefficient of X(t) and Y(t); C_{XY}(t) is the inverse Fourier transform; X(f), Y(f) are the Fourier transforms of X(t) and Y(t); Y*(f) is the complex conjugate of Y(t); * is the conjugate of a complex number;
respectively calculating the Fourier correlation coefficients of X(t) and Y(t) within the time from 0 to t3, and calculating the moments t4, t5, t6, t7, t8, 19 corresponding to the maximum values of the Fourier correlation coefficients of y1, y2, y3, y4, y5, y6, which are the delay times between the inlet NOx concentration and its influencing factors;
according to the calculated delay times t4, t5, t6, 7, t8, t9, correcting the collected data of the factors influencing the inlet NOx concentration at the current time T, that is, correcting the unit load, the total air volume, total coal quantity, total primary air volume, total secondary air volume, and coal grinding quantity at time T to the unit load, total air volume, total coal quantity, total primary air volume, total secondary air volume, and coal grinding quantity at times (T−t4), (T−t5), (T−t6), (T−t7), (T−t8), (T−t9) respectively; and
determining that the output variable used for prediction is the corrected inlet NOx concentration value, and the input variables are the corrected unit load, total air volume, total coal quantity, total primary air volume, total secondary air volume, and coal grinding quantity.

5. The method according to claim 1, wherein the step of S104 comprises:
using the Zeldovich mechanism model to construct the prediction model according to factors of temperature, oxygen concentration, nitrogen concentration, pressure, reaction time, and activation energy;
using the BP neural network model as the machine learning algorithm, wherein the BP neural network model is a three-layer model comprising an input layer, a hidden layer, and an output layer, the input layer consists of six input variables of the corrected unit load, total air volume, total coal quantity, total primary air volume, total secondary air volume, and coal grinding quantity, and the output layer is the corrected inlet NOx concentration value, the parameters of the BP neural network model are the weights and thresholds between the input layer and the hidden layer, and the weights and thresholds between the hidden layer and the output layer, the correction of the above weights and thresholds is carried out through the global error function, which is defined by formulas 3-5:
$$E ( θ ) = Data ( θ ) + λ Physic s ( θ ) ; \qquad Formula 3$$
$$Data ( θ ) = \frac{1}{2 N} {\sum }_{i = 1}^{N} {( {y}_{i} - {\hat{y}}_{Data \_ i} )}^{2} ; \qquad Formula 4$$
$$Physic ( θ ) = \frac{1}{2 N} {\sum }_{i = 1}^{N} {( {y}_{Physics \_ i} - {\hat{y}}_{Physics \_ i} )}^{2} ; \qquad Formula 5$$
wherein, E(θ) is the global error function, Data(θ) is the error function of the BP neural network model; Physics(θ) is the error function of the physical model; λ is the weight coefficient of the physical constraint term, which is obtained by the empirical method or through the genetic optimization algorithm; yᵢ is the actual inlet NOx concentration value; ŷ_{Data_i} is the predicted inlet NOx concentration value by the BP neural network model; ŷ_{Physics_i} is the predicted inlet NOx concentration value by the physical model; and
by minimizing E(θ), obtaining the optimal weights and thresholds between the input layer and the hidden layer, and the optimal weights and thresholds between the hidden layer and the output layer, and then determining the BP neural network model with the optimal physical constraints.

6. The method according to claim 5, wherein the step of S105 comprises:
collecting the factors influencing the inlet NOx concentration at the current moment, making a correction according to the calculated delay times t4, t5, t6, t7, t8, t9, and feeding into the prediction model with the optimal physical constraints to obtain the inlet NOx concentration value at the current moment.

7. A device for predicting inlet NOx concentration of a denitrification system in a thermal power plant considering measurement delay, comprising:
a collection module for determining factors influencing inlet NOx concentration of a denitrification reactor, and collecting data of the inlet NOx concentration and the factors influencing the inlet NOx concentration of the denitrification reactor;
a correction module for determining measurement delay times of the inlet NOx concentration, and correcting the inlet NOx concentration according to the measurement delay times to obtain the inlet NOx concentration without delay;
a calculation module for using a Fourier transform correlation coefficient method to calculate correlation coefficients between the inlet NOx concentration and each influencing factor, obtaining a delay time between each influencing factor and the inlet NOx concentration according to the correlation coefficients, correcting each influencing factor according to the delay time to obtain the data of the factors influencing the inlet NOx concentration without delay, and determining output variables and input characteristic parameter variables used for prediction; and
a prediction model module for, based on the inlet NOx concentration without delay and the data of the factors influencing the inlet NOx concentration without delay, and according to the determined output variables and input characteristic parameter variables, using a machine learning algorithm based on physical constraints to train and complete a prediction model; and collecting the data of the factors influencing the inlet NOx concentration at the current moment, making a correction according to the calculated delay time, feeding into the prediction model, and obtaining the inlet NOx concentration value at the current moment.

8. The device according to claim 7, wherein the collection module is further used for:
according to the generation mechanism of NOx in the flue gas of thermal power plants, determining that the factors influencing the inlet NOx concentration includes: unit load, total air volume, total coal quantity, total primary air volume, total secondary air volume, and coal grinding quantity; and
collecting the data of the inlet NOx concentration and the factors influencing the inlet NOx concentration within a predetermined past time from the DCS system or SIS system of the thermal power plant at a predetermined sampling interval;
the correction module is further used for:
according to the inlet NOx concentration measured by CEMS, determining that the measurement delay time t1 includes the delay time of a gas sampling system t_sampling, the delay time of a transmission pipeline t_transmission, and the response time of an analyzer t_response, wherein, the delay time of a gas sampling system t_sampling is the delay caused by a sampling pipeline, a sampling pump, a filter, etc., and is determined by the ratio of the length of the sampling pipeline L1 to the flow rate of the sampling pump V1, that is, t_sampling=L1/V1, the delay time of a transmission pipeline t_transmission is the delay of the measurement signal transmitted from the sampling point to the instrument CEMS, and is determined by the transmission distance of the signal L2 and the transmission rate V2, that is, t_transmission=L2/V2, the response time of an analyzer t_response is the time required for the CEMS analyzer instrument when the input signal changes; and
calculating the measurement delay time t1 according to formula 1, and correcting the collected data of the inlet NOx concentration at the current time t2, that is, correcting the inlet NOx concentration value at time t2 to the inlet NOx concentration value at time (t2-t1):
$$t 1 = t\_sampling + t\_transmission + t\_response ; \qquad Formula 1$$
the calculation module is further used for:
letting the inlet NOx concentration factor be X(t), and the factors influencing the inlet NOx concentration be Y(t)={y1(t), y2(t), y3(t), y4(t), y5(t), y6(t)}, where y1, y2, y3, y4, y5, y6 are the unit load, total air volume, total coal quantity, total primary air volume, total secondary air volume, and coal grinding quantity respectively, t is the index number, t=1, 2, . . . , N, and N is the number of collected inlet NOx concentration samples, then, determining the Fourier cross correlation coefficient according to formula 2:
$${C}_{X Y} ( t ) = {F}^{⋀} \{ - 1 \} \{ X ( f ) * ( Y * ( f ) ) \} ; \qquad Formula 2$$
wherein, C_{XY}(t) is the Fourier cross correlation coefficient of X(t) and Y(t); F\hat{ }{−I} is the inverse Fourier transform; X(f), Y(f) are the Fourier transforms of X(t) and Y(t); Y*(f) is the complex conjugate of Y(t); * is the conjugate of a complex number;
respectively calculating the Fourier correlation coefficients of X(t) and Y(t) within the time from 0 to t3, and calculating the moments t4, t5, t6, t7, t8, 19 corresponding to the maximum values of the Fourier correlation coefficients of y1, y2, y3, y4, y5, y6, which are the delay times between the inlet NOx concentration and its influencing factors;
according to the calculated delay times t4, t5, t6, t7, t8, t9, correcting the collected data of the factors influencing the inlet NOx concentration at the current time T, that is, correcting the unit load, total air volume, total coal quantity, total primary air volume, total secondary air volume, and coal grinding quantity at time T to the unit load, total air volume, total coal quantity, total primary air volume, total secondary air volume, and coal grinding quantity at times (T−t4), (T−t5), (T−t6), (T−t7), (T−t8), (T−t9) respectively; and
determining that the output variable used for prediction is the corrected inlet NOx concentration value, and the input variables are the corrected unit load, total air volume, total coal quantity, total primary air volume, total secondary air volume, and coal grinding quantity; and
the prediction model module is further used for:
using the Zeldovich mechanism model to construct the prediction model according to factors such as temperature, oxygen concentration, nitrogen concentration, pressure, reaction time, and activation energy;
using the BP neural network model as the machine learning algorithm, wherein, the BP neural network model is a three-layer model comprising an input layer, a hidden layer, and an output layer, the input layer consists of six input variables of the corrected unit load, total air volume, total coal quantity, total primary air volume, total secondary air volume, and coal grinding quantity, the output layer is the corrected inlet NOx concentration value, the parameters of the BP neural network model are the weights and thresholds between the input layer and the hidden layer, and the weights and thresholds between the hidden layer and the output layer, the above weights and thresholds are carried through the global error function, which is defined by formula 3-formula 5:
$$E ( θ ) = Data ( θ ) + λ Physic s ( θ ) ; \qquad Formula 3$$
$$Data ( θ ) = \frac{1}{2 N} {\sum }_{i = 1}^{N} {( {y}_{i} - {\hat{y}}_{Data \_ i} )}^{2} ; \qquad Formula 4$$
$$Physic ( θ ) = \frac{1}{2 N} {\sum }_{i = 1}^{N} {( {y}_{Physics \_ i} - {\hat{y}}_{Physics \_ i} )}^{2} ; \qquad Formula 5$$
wherein, E(θ) is the global error function, Data(θ) is the error function of the BP neural network model; Physics(θ) is the error function of the physical model; λ is the weight coefficient of the physical constraint term, which is obtained by the empirical method or through the genetic optimization algorithm; yᵢ is the actual inlet NOx concentration value; ŷ_{Data_i} is the predicted inlet NOx concentration value by the BP neural network model; ŷ_{Physics_i} is the predicted inlet NOx concentration value by the physical model;
by minimizing E(θ), obtaining the optimal weights and thresholds between the input layer and the hidden layer, and the optimal weights and thresholds between the hidden layer and the output layer, and then determining the BP neural network model with the optimal physical constraints; and
collecting the factors influencing the inlet NOx concentration at the current moment, making a correction according to the calculated delay times t4, t5, t6, t7, t8, t9, and feeding into the prediction model with the optimal physical constraints to obtain the inlet NOx concentration value at the current moment.

9. An electronic device comprising a memory, a processor, and a computer program stored on the memory and executable on the processor, wherein, when the computer program is executed by the processor, the steps of the method for predicting inlet NOx concentration of a denitrification system in a thermal power plant considering measurement delay according to claim 1 is implemented.

10. A computer readable storage medium on which an implementation program for information transmission is stored, wherein, when the program is executed by a processor, the steps of the method for predicting inlet NOx concentration of a denitrification system in a thermal power plant considering measurement delay according to claim 1 is implemented.
